(19) United States
(12) Patent Application Publication
(10) Pub. No.: US 2026/0136855 A1
(43) Pub. Date: May 14, 2026

(54) METHOD OF SELECTIVE DEPOSITION ON SUBSTRATE, SUBSTRATE FABRICATED THEREBY, SEMICONDUCTOR DEVICE, AND ELECTRONIC DEVICE COMPRISING SAME

(71) Applicants: SAMSUNG ELECTRONICS CO., LTD., Suwon-si (KR); IUCF-HYU (Industry-University Cooperation Foundation Hanyang University)

(72) Inventors: Suk Gyu HAHM, Suwon-si (KR); Byung Ha PARK, Suwon-si (KR); Myong Jong KWON, Suwon-si (KR); Myung-Mo SUNG, Seoul (KR); Juyeong LEE, Seoul (KR)

(21) Appl. No.: 19/382,478

(22) Filed: Nov. 7, 2025

(30) Foreign Application Priority Data
Nov. 8, 2024 (KR) 10-2024-0158405
Nov. 6, 2025 (KR) 10-2025-0166389

(51) Int. Cl. H01L 21/02; C23C 16/455

(52) U.S. Cl. CPC H10P 14/69215; C23C 16/45553; H10P 14/6339; H10P 14/6514; H10P 14/668

(57) ABSTRACT

A method of selectively depositing silicon oxide on a substrate, a method of fabricating a semiconductor device, and a semiconductor device are provided. The method includes: providing a substrate that includes a first surface including silicon oxide and a second surface including silicon nitride in a deposition chamber; selectively depositing a metal oxide precursor on the first surface of the substrate; treating the substrate with an oxygen plasma; and treating the substrate with a silicon oxide precursor.

### CROSS-REFERENCE TO RELATED APPLICATION

This application is based on and claims priority to Korean Patent Application Nos. 10-2024-0158405 and 10-2025-0166389, filed in the Korean Intellectual Property Office on Nov. 8, 2024, and Nov. 6, 2025, respectively, and all the benefits accruing therefrom under 35 U.S.C. § 119, the content of which, in its entirety, is incorporated herein by reference.

### BACKGROUND

### 1. Field

A method of selectively depositing a silicon oxide to provide a substrate that includes a surface including the silicon oxide and silicon nitride, a substrate fabricated by the method, and a semiconductor device, and an electronic device including the substrate are disclosed.

### 2. Description of the Related Art

The semiconductor device industry faces many challenges due to commercial interests and trends toward device miniaturization including a rapid expansion of nanoscale features in semiconductor devices. The challenges often involve fabrication of complex semiconductor devices that utilize multiple lithography steps and etching processes. In addition, as device features continuously become smaller and smaller the gaps or spaces between the features also become smaller. As a result, it becomes much more difficult to physically and electronically separate one feature from an adjacent feature in such devices. As features such as trenches, gaps, and the like are often formed in irregular shapes with high aspect ratios, it increasingly becomes difficult to fill the trenches or gaps with high-quality dielectric materials by using conventional filling or deposition methods. Moreover, there is a need and interest to provide a lower-cost alternative to the use of relatively expensive Extreme Ultra-Violet (EUV) patterning processes for patterning complex architectures with very small features.

One alternative to achieve smaller and physically separate device features may be selective deposition in the device miniaturization (manufacturing) process. In some cases, the deposition processes may be inherently selective toward some surfaces based on surface chemistry. However, such processes are uncommon, and in general, specific to reactants used, materials formed, and substrate surfaces. For instance, one method may utilize an inhibitor to block deposition of a material in or within a specific region, while selectively depositing the material in another region of interest. However, if two regions on the surface have similar surface characteristics or similar reactivity to the inhibitor, selectively depositing a specific material in the specific region of interest becomes challenging.

Accordingly, the development of new methods for selectively depositing a desired material in a specific region to provide ever smaller device features in semiconductor devices is needed

### SUMMARY

An embodiment provides a method for selectively depositing a specific material on a surface of a substrate which includes two different surfaces having similar chemical reactivity.

Another embodiment provides a substrate fabricated by the method, on which a specific material is deposited in a specific region of interest.

Another embodiment provides a semiconductor device including a substrate having two different surface compositions and having a specific material deposited on one of the two surfaces.

Another embodiment provides an electronic device including the semiconductor device.

An embodiment provides a method of selectively depositing a silicon oxide on a surface of a substrate. The method includes: providing a substrate that includes a first surface including silicon oxide, and a second surface including silicon nitride in a deposition chamber; selectively depositing a metal oxide precursor on the first surface of the substrate; treating the substrate with an oxygen (O₂) plasma; and supplying a silicon oxide precursor to the substrate. The silicon oxide may be represented by SiO₂, and the silicon nitride may be represented by SiNx and x is 0.5≤x≤2.

The treating the substrate with the oxygen (O₂) plasma includes converting the metal oxide precursor deposited on the first surface into a metal oxide.

The metal oxide precursor includes an oxide precursor of a metal including aluminum, zinc, titanium, hafnium, zirconium, or a combination thereof.

The metal oxide precursor on the first surface may be formed by depositing a first reactant including a metal on the first surface, and supplying a second reactant including a phenyl group or a biphenyl group.

The first reactant includes an organic compound of the metal, a halide of the metal, an alkoxide of the metal, an amine compound of the metal, or a combination thereof.

The first reactant includes trimethyl aluminum, trichloro aluminum, diethyl amine, (ethylcyclopentadienyl)tris(dimethylamido)titanium(IV) (EtCp)Ti(NMe₂)₃, titanium tetramethoxide (Ti(OCH₃)₄), tetrakis(diethylamido)titanium(IV) (TDEAT), tetrakis(dimethylamido)titanium(IV) (TDMAT), titanium tetrachloride (TiCl₄), titanium(IV) isopropoxide (Ti(Pro)₄), tetrakis(diethylamino)hafnium(IV) (TDEAHf), hafnium(IV) chloride (HfCl₄), hafnium(IV) t-butoxide (hafnium(IV) tert-butoxide, Hft(BuO)₄), tetrakis(dimethylamino)hafnium(IV) (TDMAHf), zirconium-t-(butoxide)₄ (Zr-t(Bu)₄), tetrakis(dimethylamino)zirconium (TDMA-Zr), zirconium(IV) chloride (ZrCl₄), or a combination thereof.

The second reactant includes a substituted or unsubstituted phenol or a substituted or unsubstituted biphenyl group-containing compound.

The substituted or unsubstituted phenol includes an unsubstituted phenol, a mercapto phenol, a phenol substituted with an alkyl group, a phenol substituted with a fluorine and an alkyl group, or a combination thereof.

The metal oxide precursor may be represented by Chemical Formula 1:

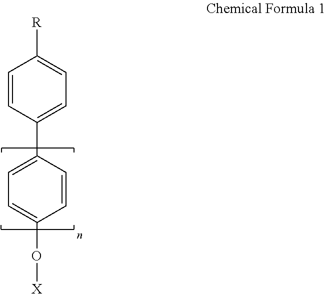

In Chemical Formula 1,
R may be hydrogen, a C1 to C10 alkyl group, a halogen atom, or a mercapto group,
X may be Al, Zn, Ti, Hf, or Zr, coordinated without or with an organic group, and
n may be 0 or 1.

The silicon oxide precursor may be deposited on the second surface treated with the oxygen (O₂) plasma by atomic layer deposition (ALD) to form silicon oxide.

The silicon oxide precursor includes an amino silane compound, an alkoxy silane compound, a silane halide, or a combination thereof.

The silicon oxide precursor includes silicon tetrachloride (SiCl₄), tetraethyl orthosilicate (TEOS), diisopropylaminosilane (DIPAS), bis(diethylamino)silane (BDEAS), or a combination thereof.

A deposition method according to an embodiment may further include removing the metal oxide present on the first surface after treating the substrate with the silicon oxide precursor.

A width of the second surface may be less than or equal to about 5 nanometers.

In another embodiment, a method of fabricating a semiconductor device comprising: providing a structure having a laminate in which a silicon oxide layer and a silicon nitride layer are alternately laminated, and an opening penetrating the laminate; selectively depositing a metal oxide precursor on an exposed surface of the silicon oxide layer in the opening; supplying an oxygen plasma into the opening; and supplying a silicon oxide precursor into the opening.

The metal oxide precursor may be an oxide precursor of a metal comprising aluminum, zinc, titanium, hafnium, zirconium, or a combination thereof.

In the method of fabricating the semiconductor device, the supplying oxygen plasma into the opening may include converting the metal oxide precursor deposited on the exposed surface of the silicon oxide layer in the opening into a metal oxide.

The method may further include removing the metal oxide after the supplying the silicon oxide precursor into the opening.

In the opening of the structure a first exposed surface including silicon oxide and a second exposed surface including silicon nitride may exist, and a width of the second exposed surface may be less than or equal to about 5 nanometers.

The selectively depositing the metal oxide precursor on the exposed surface of the silicon oxide layer in the opening may comprise depositing a first reactant including a metal on the first exposed surface of the silicon oxide layer, and supplying a second reactant including a phenyl group or a biphenyl group.

According to a selective deposition method according to an embodiment, a silicon oxide precursor may be selectively deposited on a surface of a substrate that includes a surface including silicon nitride in the presence of an inhibitor, e.g., an inhibitor layer, that selectively binds to a surface of the substrate including silicon oxide. The process being selective in that silicon nitride and silicon oxide have a small difference in chemical reactivity. According to the method, even when the width of the surface including silicon nitride is as narrow, e.g., a line width of less than or equal to about 5 nanometers (nm), a silicon oxide film can be easily formed selectively on the surface including silicon nitride in the absence of a masked exposure and etching process. Accordingly, the process efficiency and cost can be significantly reduced, and it can be advantageously used in the fabrication of semiconductor devices including fine patterns of less than or equal to about 5 nm. A substrate selectively including a thin film of silicon oxide only in a specific region fabricated by a method according to an embodiment can be advantageously applied to a semiconductor device, such as a charge trap layer of a three-dimensional semiconductor device.

### BRIEF DESCRIPTION OF THE DRAWINGS

FIG. 1 is a schematic view schematically illustrating each process step of a method for depositing silicon oxide only on surface, SiNx, according to an embodiment.

FIG. 2 is a schematic view showing the state before the cleaning and pre-treatment process of a substrate including a surface of silicon oxide and a surface of silicon nitride (upper portion of FIG. 2) and the state after the cleaning and pre-treatment process (lower portion of FIG. 2).

FIG. 3 is a simple drawing showing the step-by-step process of synthesizing and depositing a zinc (Zn) oxide precursor on the surface of silicon oxide.

FIG. 4 is a simple drawing showing the step-by-step process of synthesizing and depositing an aluminum (Al) oxide precursor on the surface of silicon oxide.

FIG. 5 is a simple drawing showing the step-by-step process of synthesizing and depositing a titanium (Ti) oxide precursor on the surface of silicon oxide.

FIG. 6 is a schematic view showing the process of converting a zinc (Zn) oxide precursor formed on the surface of silicon oxide into zinc oxide through oxygen (O₂) plasma treatment, and simultaneously generating a hydroxyl group (—OH) on the surface of silicon nitride.

FIG. 7 is a schematic view showing the conversion of an aluminum (Al) oxide precursor formed on the surface of silicon oxide into aluminum oxide through oxygen (O₂) plasma treatment, and at the same time, the generation of hydroxyl groups (—OH) on the surface of silicon nitride.

FIG. 8 is a schematic view showing the conversion of a titanium (Ti) oxide precursor formed on the surface of silicon oxide into titanium oxide through oxygen (O₂) plasma treatment, and at the same time, the generation of hydroxyl groups (—OH) on the surface of silicon nitride.

FIG. 9 is a schematic view showing the formation of a silicon oxide film on the surface of silicon nitride of a substrate on which zinc (Zn) oxide is formed on the surface of silicon oxide.

FIG. 10 is a schematic view showing the formation of a silicon oxide film on the surface of silicon nitride of a substrate on which aluminum (Al) oxide is formed on the surface of silicon oxide.

FIG. 11 is a schematic view showing the formation of a silicon oxide film on the surface of silicon nitride of a substrate on which titanium (Ti) oxide is formed on the surface of silicon oxide.

FIG. 12 is a cross-sectional view schematically illustrating a process for forming a channel opening in a three-dimensional semiconductor device using a conventional method.

FIG. 13A is a cross-sectional view of a portion of (f) of FIG. 12, where a charge trap layer disposed between a tunnel oxide and a blocking oxide and a gate electrode of a three-dimensional semiconductor device fabricated by a conventional method are shown.

FIG. 13B is a cross-sectional view of a corresponding portion of FIG. 13A, where also a charge trap layer disposed between a tunnel oxide and a blocking oxide and a gate electrode of a three-dimensional semiconductor device are shown, where the three-dimensional semiconductor device is fabricated by a method according to an embodiment by a method according to an embodiment.

FIG. 14 is a graph showing the thicknesses (nanometers, nm) of silicon oxide films grown on a silicon oxide (SiO₂) substrate and a silicon nitride (SiNx) substrate, respectively, versus the number of supply cycles of silicon oxide precursor, using zinc-4-mercaptophenol (Zn4MP) as a metal oxide precursor according to a method of an embodiment.

FIG. 15 shows photographs and graphs showing the morphology of a silicon oxide film formed on the surface of each substrate, and the step difference with respect to a portion where a silicon oxide film is not formed, measured using AFM (Atomic Force Microscopy) when the number of supply cycles of silicon oxide precursor is 30, 50, 100, and 150, respectively, for a silicon oxide (SiO₂) substrate and a silicon nitride (SiNx) substrate shown in the graph of FIG. 14.

FIG. 16 is a graph showing the thicknesses (nanometers, nm) of silicon oxide films formed on a silicon oxide (SiO₂) substrate and a silicon nitride (SiNx) substrate, respectively, versus the number of supply cycles of silicon oxide precursor, using an aluminum-phenol precursor as a metal oxide precursor according to a method of an embodiment.

FIG. 17 shows photographs and graphs showing the morphology of a silicon oxide film formed on the surface of each substrate, and the step difference with respect to a portion where a silicon oxide film is not formed, measured using AFM (Atomic Force Microscopy) when the number of supply cycles of silicon oxide precursor is 30, 50, 100, and 150, respectively, for a silicon oxide (SiO₂) substrate and a silicon nitride (SiNx) substrate shown in the graph of FIG. 16.

FIG. 18 is a graph showing the thicknesses (nanometers, nm) of silicon oxide films formed on a silicon oxide (SiO₂) substrate and a silicon nitride (SiNx) substrate, respectively, versus the number of supply cycles of silicon oxide precursor, using a titanium-phenol precursor as a metal oxide precursor according to a method of an embodiment.

FIG. 19 shows photographs and graphs showing the morphology of a silicon oxide film formed on the surface of each substrate, and the step difference with respect to a portion where a silicon oxide film is not formed, measured using AFM (Atomic Force Microscopy) when the number of supply cycles of silicon oxide precursor is 30, 50, 100, and 150, respectively, for a silicon oxide (SiO₂) substrate and a silicon nitride (SiNx) substrate shown in the graph of FIG. 18.

FIG. 20 is a graph showing the thicknesses (nanometers, nm) of silicon oxide films formed on a silicon oxide (SiO₂) substrate and a silicon nitride (SiNx) substrate, respectively, versus the number of supply cycles of silicon oxide precursor, using dimethylaminotrimethyl silane (DMATMS), an organic silane compound, as a precursor instead of a metal oxide precursor, as a comparative example.

FIG. 21 shows photographs and graphs showing the morphology of a silicon oxide film formed on the surface of each substrate, and the step difference with respect to a portion where a silicon oxide film is not formed, measured using AFM (Atomic Force Microscopy) when the number of supply cycles of silicon oxide precursor is 30, 50, and 100, respectively, for a silicon oxide (SiO₂) substrate and a silicon nitride (SiNx) substrate shown in the graph of FIG. 20.

FIG. 22 is a transmission electron microscopy (TEM) image showing the result of forming a silicon oxide film substantially only on the surface of silicon nitride (SiNx) by supplying a silicon oxide precursor to a substrate on which silicon oxide (SiO₂) and silicon nitride (SiNx) are alternately laminated using zinc-4-mercaptophenol as a metal oxide precursor according to a method of an embodiment.

FIG. 23 is a transmission electron microscope (TEM) image showing the result of forming a silicon oxide film substantially only on the surface of silicon nitride (SiNx) by supplying a silicon oxide precursor to a substrate on which silicon oxide (SiO₂) and silicon nitride (SiNx) are alternately stacked using aluminum-phenol as a metal oxide precursor according to a method of an embodiment.

FIG. 24 is an image showing the analysis results by energy dispersive spectroscopy (EDS) for the substrate shown in FIG. 22.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

The terminology used herein is used to describe embodiments only, and is not intended to limit the present disclosure. The singular expression includes the plural expression unless the context clearly dictates otherwise.

The term “combination thereof” herein means a mixture, a stack, a composite, a copolymer, an alloy, a blend, a reaction product, and the like of constituents.

Here, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The term “layer” includes a construction having a shape formed on a part of a region, in addition to a construction having a shape formed on an entire region.

As used herein, “size” means an average particle diameter in the case of a sphere and the length of the longest portion in the case of a non-spherical shape. The size may be measured by a method well known to those skilled in the art, for example, may be measured by a particle size analyzer, or may be measured by a transmission electron micrograph or a scanning electron micrograph. Alternatively, it is possible to obtain an average particle diameter value by measuring utilizing a dynamic light scattering method, performing data analysis, counting the number of particles for each particle size range, and calculating from these data.

Here, the term “or” is not to be construed as an exclusive meaning, and for example, “A or B” is construed to include A, B, A+B, and/or the like.

The term “selectively depositing” refers to the molecular deposition of a material A on an exposed surface, e.g., a surface of a substrate, that includes a surface region X and a surface region Y in which the deposition of the material A on surface region X accounts for at least 90% by weight of the total deposition of material A (100% by weight of material A) based on equal surface regions X and Y present on a substrate under identical deposition conditions. For example, in a atomic/molecular deposition processes known to a person of ordinary skill a substrate, or two separate substrates with surface X and surface Y, respectively, having equal areas of surface region X and surface region Y, the amount of deposition of material A on surface region X is at least 90% by weight, at least 95 wt %, or at least 97 wt % of the total deposition of material A on surface region X and surface region Y. In many instances, the selectively depositing of a material A on a surface region X relative to surface region Y may exhibit near 100 wt % selectivity.

As used herein, when specific definition is not otherwise provided, “substituted” refers to replacement of one or more hydrogen atoms in a given functional group by one or more substituents selected from a halogen atom (F, Cl, Br, or I), a hydroxy group, a nitro group, a cyano group, an amino group (—NH₂, —NH(R¹⁰⁰), or —N(R¹⁰¹)(R¹⁰²), wherein R¹⁰⁰, R¹⁰¹, and R¹⁰² are the same or different and are each independently a C1 to C10 alkyl group), an amidino group, a hydrazine group, a hydrazone group, a carboxyl group, an ester group, a ketone group, a substituted or unsubstituted alkyl group, a substituted or unsubstituted alicyclic organic group (e.g., a cycloalkyl group, etc.), a substituted or unsubstituted aryl group (e.g., a benzyl group, a naphthyl group, a fluorenyl group, etc.), a substituted or unsubstituted alkenyl group, a substituted or unsubstituted alkynyl group, a substituted or unsubstituted heteroaryl group, and a substituted or unsubstituted heterocyclic group, and the substituents may be linked to each other to form a ring.

As used herein, when specific definition is not otherwise provided, “alkyl group” refers to a C1 to C30 alkyl group, specifically a C1 to C15 alkyl group, “cycloalkyl group” refers to a C3 to C30 cycloalkyl group, specifically a C3 to C18 cycloalkyl group, “alkoxy group” refers to a C1 to C30 alkoxy group, specifically a C1 to C18 alkoxy group, “ester group” refers to a C2 to C30 ester group, specifically a C2 to C18 ester group, “ketone group” refers to a C2 to C30 ketone group, specifically a C2 to C18 ketone group, “aryl group” refers to a C6 to C30 aryl group, specifically a C6 to C18 aryl group, and “alkenyl group” refers to a C2 to C30 alkenyl group, specifically a C2 to C18 alkenyl group.

Hereinafter, embodiments of the present disclosure will be described in detail with reference to the drawings attached to the present specification.

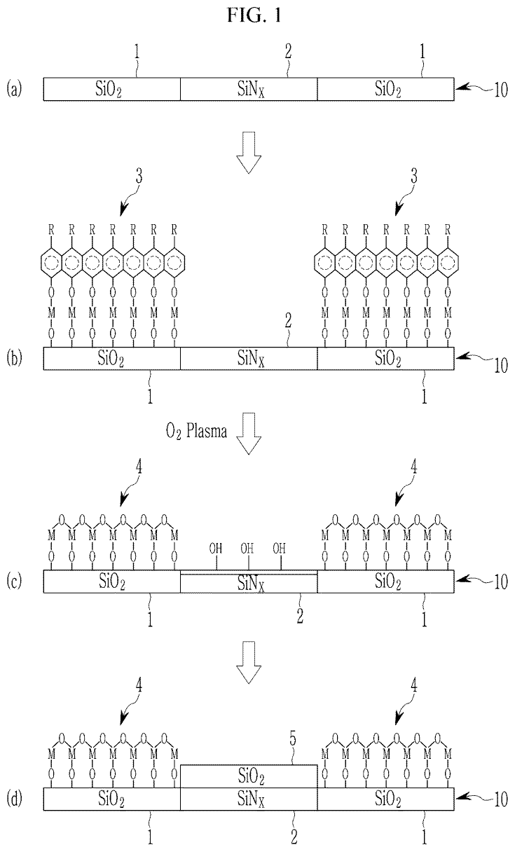

FIG. 1 is a schematic view schematically illustrating each process step of a method for depositing silicon oxide only on a specific surface according to an embodiment.

Referring to FIG. 1, a method for depositing silicon oxide according to an embodiment includes preparing a substrate 10 including a first surface 1 including silicon oxide and a second surface 2 including silicon nitride, as shown in (a) of FIG. 1, and placing it in a chamber (not shown) capable of performing atomic layer deposition (ALD). Here, the silicon oxide may be represented by SiO₂, and the silicon nitride may be represented by SiNx, where x is 0.5≤x≤2.

Thereafter, within the chamber, as shown in (b) of FIG. 1, a metal oxide precursor 3 is selectively deposited only on the first surface 1 of the substrate 10.

As shown in (b) of FIG. 1, the metal oxide precursor 3 is bonded to the first surface 1 of the substrate 10 by the metal indicated as M through an oxygen (O) atom of the first surface 1. Additionally, the metal M is bonded to a phenyl group through another oxygen (O) atom. That is, in the method according to an embodiment, the metal oxide precursor 3 is such that the metal (M) is bonded to the first surface 1 through an oxygen (O) atom at the first surface 1, and further, the metal is bonded to a phenyl group that bonds to an oxygen (O) atom of the metal oxide precursor 3. The metal (M) may include aluminum (Al), zinc (Zn), titanium (Ti), hafnium (Hf), zirconium (Zr), or a combination thereof, but is not limited thereto. The metal oxide precursor 3 may be bonded to the first surface 1 to be represented by Chemical Formula 1-1:

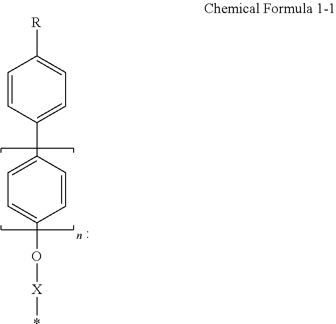

In Chemical Formula 1-1,
R may be hydrogen, a C1 to C10 alkyl group, a halogen atom, or a mercapto group,
X may be Al, Zn, Ti, Hf, or Zr, coordinated without or with an organic group,
n may be 0 or 1, and
* may be a linking position to the oxygen (O) in the first surface 1 of the substrate 10.

As described above, the metal oxide precursor 3 may be bonded to the oxygen (O) of the hydroxyl group (—OH) in the first surface 1, and may also be bonded to the phenyl group or biphenyl group via another oxygen (O) atom. Accordingly, the metal oxide precursor 3 may also be represented by Chemical Formula 1-2:

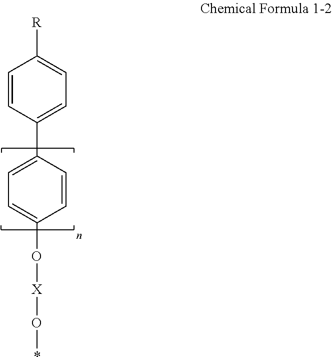

In Chemical Formula 1-2,
R may be hydrogen, a C1 to C10 alkyl group, a halogen atom, or a mercapto group,
X may be Al, Zn, Ti, Hf, or Zr, coordinated without or with an organic group,
n may be 0 or 1, and
* may be a linking position to the the first surface 1.

As shown in (b) of FIG. 1, in a method according to an embodiment, the metal oxide precursor 3 may form a monolayer on the first surface 1. The metal oxide precursors 3 may be formed as a monolayer on the first surface 1 using, for example, molecular layer deposition (hereinafter, abbreviated as MLD).

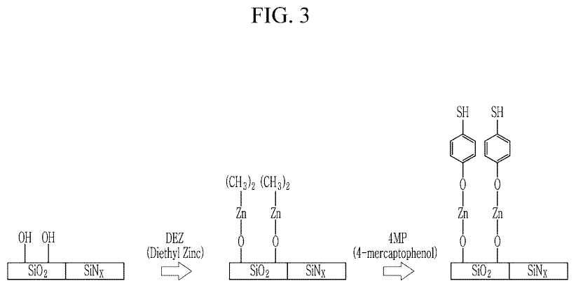

The molecular layer deposition (MLD) is a vapor phase thin film deposition method based on sequential self-limiting surface reactions. This is essentially similar to the well-established atomic layer deposition (ALD) process, but with the difference that while ALD is exclusively limited to inorganic coatings, precursor materials in MLD can also use small bifunctional organic molecules. Accordingly, MLD can not only grow organic layers in a process similar to polymerization, but also form organic-inorganic hybrid materials by linking together two types of monomers (building blocks), organic and inorganic, in a controlled manner. A method for selectively synthesizing a metal oxide precursor 3 only on the first surface 1 of a substrate 10 using MLD is described in detail below with reference to FIGS. 3 to 5.

As described above, the metal oxide precursor 3 formed only on the first surface 1 can then be converted into a metal oxide 4 by treating it with oxygen (O₂) plasma, and this is illustrated in (c) of FIG. 1. As shown in (c) of FIG. 1, the metal oxide precursors 3 formed on the first surface 1 are converted into metal oxide 4 by oxygen plasma, forming a monolayer of the metal oxide 4 on the first surface 1. The monolayer of metal oxide 4 formed in this manner can act as an inhibitor that blocks the first surface 1 and suppresses subsequent reactions on the first surface 1.

Meanwhile, by the oxygen plasma treatment, the second surface 2 on which the metal oxide precursor 3 is not formed is activated to have a hydroxyl group (—OH).

That is, a metal oxide 4 layer acting as an inhibitor is formed on the first surface 1, and the second surface 2 is activated. When a silicon oxide precursor is supplied to the substrate 10 having a hydroxyl group, the silicon oxide precursor selectively binds only to the activated second surface 2, and can be converted into silicon oxide (SiO₂) 5 simultaneously with the binding or through an additional reaction. At this time, by controlling the supply amount of the silicon oxide precursor and the number of ALD process cycles, the thickness of the silicon oxide 5 film formed on the second surface 2 can be controlled.

The method of converting the silicon oxide precursor into silicon oxide (SiO₂) 5 is possible by applying heat to the chamber while supplying or after supplying the silicon oxide precursor, or by supplying the silicon oxide precursor together with a Lewis base or another catalyst. Alternatively, depending on the type of silicon oxide precursor, ozone (O₃) may be supplied together as a reactant, or water or water together with protons (H+) may be supplied to convert the silicon oxide precursor into silicon oxide. For example, when diisopropylamino silane (DIPAS) or bis(diethylamino)silane (BDEAS) is used as a silicon oxide precursor, ozone (O₃) may be supplied together as a reactant, and when tetraethyl orthosilicate (TEOS) is used as a silicon oxide precursor, protons (H+) may be supplied together with water to convert them into silicon oxide. The conversion of the silicon oxide precursor into silicon oxide may be accomplished using various methods known to those skilled in the art, and is not limited to the above methods.

Any silicon oxide precursor known in the art may be used, including but not limited to an amino silane compound, an alkoxy silane compound, a silane halide, or a combination thereof. In an embodiment, the silicon oxide precursor may include silicon tetrachloride (SiCl₄), tetraethyl orthosilicate (TEOS), diisopropylaminosilane (DIPAS), bis(diethylamino)silane (BDEAS), or a combination thereof, but is not limited thereto.

After selectively forming a silicon oxide film only on the second surface 2 of the substrate 10, the metal oxide 4 formed on the first surface 1 can be removed, if necessary. Removal of the metal oxide 4 can be performed using a dry etching method using chlorine (Cl₂) gas or the like, which does not affect silicon oxide (SiO₂), or using various methods known in the art.

By the method described above, it is possible to selectively deposit silicon oxide only on a surface having silicon nitride in a structure in which a surface having silicon oxide and a surface having silicon nitride, which have chemically similar properties, exist adjacent to each other. For example, a method according to one embodiment makes it possible to selectively deposit silicon oxide on a surface having silicon nitride even when the width of the surface having silicon nitride among the surfaces is very narrow, for example, less than or equal to about 5 nm. Here, the ‘width’ of the surface having the silicon nitride may indicate the length of the shortest line connecting any two points positioned on two opposite sides of the perimeter defining the surface having the silicon nitride. Alternatively, the ‘width’ of the surface having silicon nitride may indicate the length of the shortest line crossing two opposite sides of the surface having silicon nitride that are in contact with adjacent surfaces having silicon oxide.

A deposition method according to an embodiment may further include a process of cleaning and pretreating a surface of the substrate 10 including the first surface 1 and the second surface 2, before introducing the substrate 10 including the first surface 1 and the second surface 2 into the chamber, although not shown in FIG. 1. Examples of the above cleaning and pretreating processes include wet treatment using hydrofluoric acid (HF), or dry treatment using an inert gas such as oxygen plasma (O₂ plasma), ultraviolet ozone (UV ozone), or argon gas (Ar+).

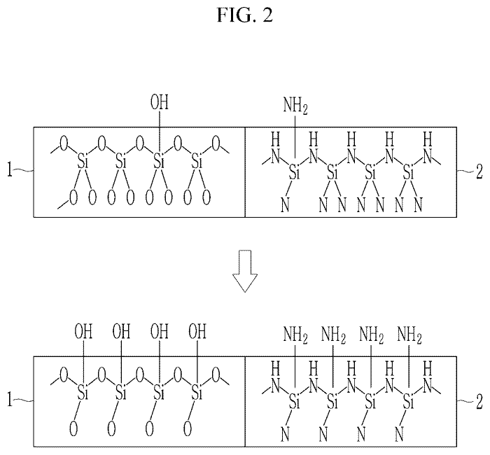

As shown in FIG. 2, the first surface 1 and the second surface 2 of the substrate 10 may have chemical species arranged unevenly on each surface before cleaning and pretreating, as shown in the upper portion of FIG. 2. For example, some hydroxyl groups may exist on the first surface 1 and some amino groups may exist on the second surface 2, but these hydroxyl groups and amino groups may not be evenly distributed over the entire surface but may exist irregularly only in some areas. By cleaning the substrate using hydrofluoric acid (HF) or pretreating it with a dry treatment method such as ultraviolet ray, ozone, or oxygen plasma, as shown in the lower portion of FIG. 2, hydroxyl groups (—OH) may be uniformly present throughout the first surface 1 and amino groups (—NH₂) may be uniformly present throughout the second surface 2, and also, carbon-based impurities may be eliminated from the substrate surface. By uniformly cleaning and pretreating the first surface 1 and the second surface 2, the subsequent deposition of the metal oxide precursor 3 may be uniformly and effectively performed only on the first surface 1, and from this, silicon oxide 5 may be uniformly deposited selectively only on the second surface 2.

Hereinafter, with reference to FIGS. 3 to 5, a method for selectively synthesizing or depositing the metal oxide precursor 3 only on the surface of silicon oxide (e.g., SiO₂) on a substrate including a surface of silicon oxide (e.g., SiO₂) and a surface of silicon nitride (e.g., SiNx, where x is 0.5≤x≤2) using MLD is described in detail.

FIG. 3 is a drawing that simply shows the steps of synthesizing or depositing a zinc (Zn) oxide precursor on the surface of silicon oxide (SiO₂) of the substrate.

As shown in FIG. 3, the zinc (Zn) oxide precursor may be obtained, by first depositing diethyl zinc as a first reactant on the surface of silicon oxide (SiO₂) of the substrate and subsequently, bonding 4-mercaptophenol as a second reactant with the diethyl zinc deposited on the surface of the silicon oxide, finally in the form of zinc (Zn) with a 4-mercaptophenoxy group bonded onto the surface of the silicon oxide (SiO₂) through an oxygen atom.

Herein, the diethyl zinc and the 4-mercaptophenol may sequentially react with the surface of the silicon oxide (SiO₂) to form the zinc oxide precursor bonded with the 4-mercaptophenoxy group shown in the final step of FIG. 3 by using molecular layer deposition (MLD). As described above, the molecular layer deposition (MLD) is a method of selectively bonding (or depositing) a first reactant or the precursor in a specific surface and subsequently, supplying a second reactant thereto, so that the second reactant may react to be bonded with the first reactant deposited on the specific surface to form a combined product of the first and second reactants as a monolayer. Accordingly, as illustrated in FIG. 1, after introducing the substrate inside a vacuum chamber which is not shown, the diethyl zinc, the first reactant is injected into the chamber to be selectively deposited on the surface of the silicon oxide, and subsequently, the 4-mercaptophenol, the second reactant is injected thereinto and reacted with the diethyl zinc bonded onto the surface of the silicon oxide, so that zinc of the diethyl zinc and oxygen of the 4-mercaptophenol may be combined each other to deposit or synthesize the zinc oxide precursor shown in the final step of FIG. 3 as a monolayer on the surface of the silicon oxide.

Specific conditions of the molecular layer deposition for synthesizing such a zinc oxide precursor may be easily established by a person skilled in the art by referring to various methods known regarding the molecular layer deposition in the art.

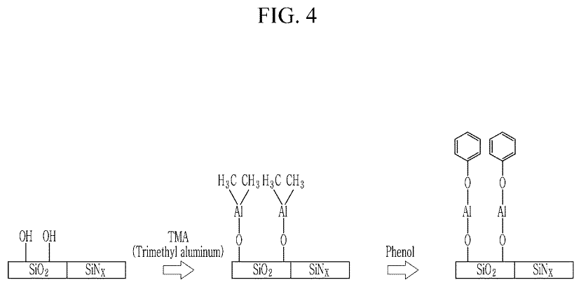

FIG. 4 is a simple drawing showing the step-by-step process of synthesizing and depositing an aluminum (Al) oxide precursor on the surface of silicon oxide (SiO₂).

As shown in FIG. 4, the aluminum (Al) oxide precursor is formed by first depositing trimethyl aluminum, a first reactant for synthesizing the same, on the surface of silicon oxide (SiO₂) of the substrate and subsequently, bonding phenol, a second reactant, with aluminum of the trimethyl aluminum deposited on the surface of the silicon oxide through a nucleophilic reaction, so that the aluminum (Al) bonded with the phenoxy group may be bonded onto the surface of the silicon oxide through an oxygen atom.

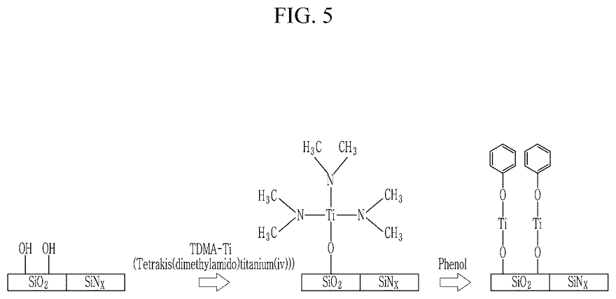

FIG. 5 is a simple drawing showing the step-by-step process of synthesizing and depositing a titanium (Ti) oxide precursor on the surface of silicon oxide (SiO₂).

As shown in FIG. 5, the titanium (Ti) oxide precursor is formed by first depositing tetrakis(dimethylamido)titanium(IV) (TDMA-Ti), a first reactant for synthesizing the titanium (Ti) oxide precursor, on the surface of silicon oxide (SiO₂) of the substrate and subsequently, bonding phenol, a second reactant, with titanium of TDMA-Ti deposited on the surface of the silicon oxide through a nucleophilic reaction, so that the titanium bonded with the phenoxy group may be bonded onto the surface of the silicon oxide through an oxygen atom.

As illustrated through FIGS. 3 to 5, the deposition method according to an embodiment may include a first step of sequentially reacting a first reactant and a second reactant selectively on the first surface (the surface of silicon oxide) through the molecular layer deposition (MLD) to form a monolayer of a metal oxide precursor and its subsequent step of converting the monolayer to a metal oxide film through oxygen plasma. This converted metal oxide film may act as an inhibitor layer blocking any subsequent deposition reaction on the first surface, and therefore, allow the silicon oxide precursor to deposit on the second surface, and subsequently form a silicon oxide film. Herein, the second surface on which the metal oxide precursor is not deposited is chemically activated, for example, by having (as shown) a hydroxyl group through the oxygen plasma treatment. As the second surface is activated by the oxygen plasma, a silicon oxide precursor may then be selectively deposited on the surface of silicon nitride.

In FIGS. 3 to 5, the case where the metal oxide precursor is precursors of zinc, aluminum, and titanium oxides is described, but the type of metal forming the metal oxide precursor is not limited thereto, and a precursor of an oxide of a metal such as hafnium or zirconium may be formed, and if necessary, a combination of the metal oxide precursors may also be formed.

In addition, in FIGS. 3 to 5, diethyl zinc, trimethyl aluminum, and tetrakis(dimethylamido)titanium (IVV) are used as the first reactants for forming the metal oxide precursor, but are not limited thereto, and various organic compounds of the metal, halides of the metal, alkoxides of the metal, amine compounds of the metal, or a combination thereof may be used as the first reactants for forming the metal oxide precursor.

For example, the first reactant of the metal oxide precursor may include trimethyl aluminum, trichloro aluminum, diethyl amine, (ethylcyclopentadienyl)tris(dimethylamido)titanium(IV) (EtCp)Ti(NMe₂)₃, titanium tetramethoxide (Ti(OCH₃)₄), tetrakis(diethylamido)titanium(IV) (TDEAT), tetrakis(dimethylamido)titanium(IV) (TDMAT), titanium tetrachloride (TiCl₄), titanium(IV) isopropoxide (Ti(Pro)₄), tetrakis(diethylamino)hafnium(IV) (TDEAHf), hafnium(IV) chloride (HfCl₄), hafnium(IV) t-butoxide (hafnium(IV) tert-butoxide, Hft(BuO)₄), tetrakis(dimethylamino)hafnium(IV) (TDMAHf), zirconium-t-(butoxide)₄ (Zr-t(Bu)₄), tetrakis(dimethylamino)zirconium (TDMA-Zr), zirconium(IV) chloride (ZrCl₄), or a combination thereof, but is not limited thereto.

In addition, as a second reactant forming the metal oxide precursor, 4-mercaptophenol or unsubstituted phenol is used in FIGS. 3 to 5, but is not limited thereto, and various substituted or unsubstituted phenol or biphenyl group-containing compounds may be used. The substituted or unsubstituted phenol may include unsubstituted phenol, mercapto phenol, phenol substituted with an alkyl group, (n)-fluorinated phenyl-alkyl-alcohol, or a combination thereof.

The metal oxide precursor uses a substituted or unsubstituted phenol or biphenyl group-containing compound as the second reactant, so that the metal oxide precursor binds to the surface of silicon oxide through an oxygen atom, while an oxygen atom derived from a hydroxyl group of the phenol or biphenyl group compound binds to the metal on the side opposite to the surface of silicon oxide. Although not intended to be bound by a specific theory, it is thought that the metal oxide precursor formed as described above is easy to self-assemble due to the structural form of the phenyl group or biphenyl group by including a phenyl group or biphenyl group on the side farthest from the surface of the silicon oxide, and thus the metal oxide precursor can form a monolayer uniformly arranged on the surface of the silicon oxide.

For example, the metal oxide precursor may be represented by Chemical Formula 1:

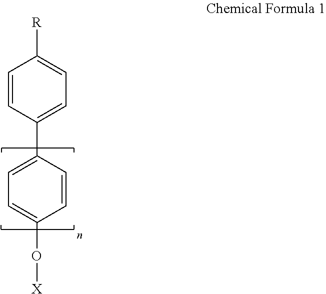

In Chemical Formula 1,
R may be hydrogen, a C1 to C10 alkyl group, a halogen atom, or a mercapto group,
X may be Al, Zn, Ti, Hf, or Zr, coordinated without or with an organic group, and
n may be 0 or 1.

The halogen atom may be fluorine (F), chlorine (Cl), bromine (Br), or iodine (I).

The organic group may be a substituted or unsubstituted C1 to C10 alkyl group, —NR′R″ (where, R′ and R″ may, each independently, be hydrogen, or a C1 to C10 alkyl group), or a combination thereof.

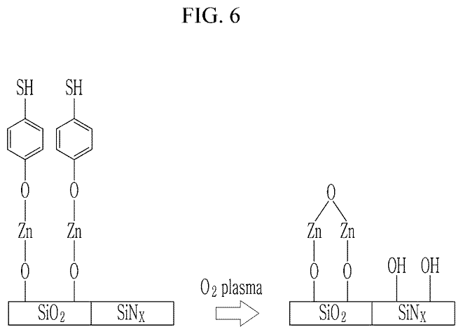

FIGS. 6 to 8 are schematic views showing the process in which the metal oxide precursor formed on the surface of the silicon oxide described through FIGS. 3 to 5 is converted into a metal oxide film by the plasma treatment described above, and at the same time, the second surface (surface of silicon nitride) on which the metal oxide precursor is not deposited is activated to have a hydroxyl group.

FIG. 6 is a view showing that when oxygen plasma is treated on the surface of silicon oxide on which the zinc oxide precursor described through FIG. 3 is formed and the surface of silicon nitride on which the precursor is not deposited, the zinc oxide precursor is converted to zinc oxide and hydroxyl groups are generated on the surface of silicon nitride.

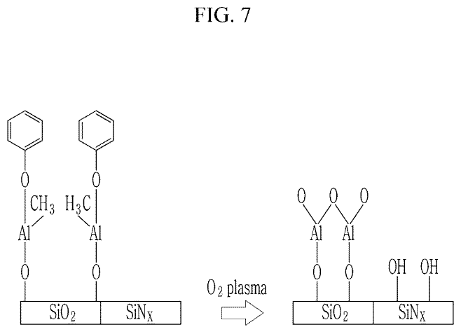

FIG. 7 is a view showing that when oxygen plasma is treated on the surface of silicon oxide on which the aluminum oxide precursor described through FIG. 4 is formed and the surface of silicon nitride on which the precursor is not deposited, the aluminum oxide precursor is converted to aluminum oxide and hydroxyl groups are generated on the surface of silicon nitride.

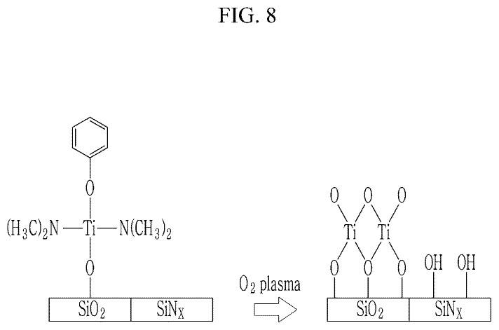

FIG. 8 is a view showing that when oxygen plasma is treated on the surface of silicon oxide on which the titanium oxide precursor described through FIG. 5 is formed and the surface of silicon nitride on which the precursor is not deposited, the titanium oxide precursor is converted to titanium oxide and hydroxyl groups are generated on the surface of silicon nitride.

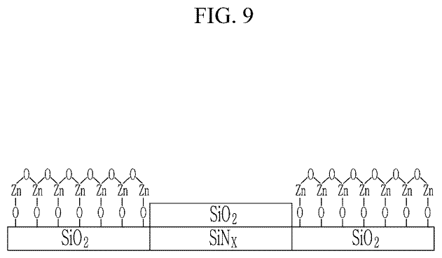

FIGS. 9 to 11 are views showing that when a silicon oxide precursor is supplied to the substrate shown in FIGS. 6 to 8, silicon oxide is not formed on the surface of silicon oxide on which a metal oxide film is formed, and a silicon oxide film is formed on the surface of silicon nitride on which hydroxyl groups are formed.

FIG. 9 is a view showing that when a silicon oxide precursor is supplied to a substrate including a surface of silicon oxide on which a zinc oxide film as shown in FIG. 6 is formed and a surface of activated silicon nitride, the silicon oxide precursor is deposited on the surface of the silicon nitride to form a silicon oxide film.

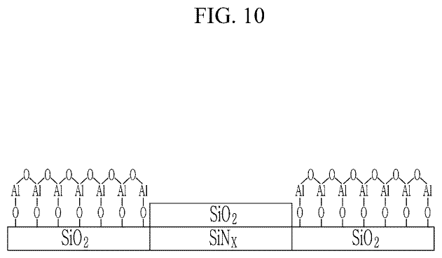

FIG. 10 is a view showing that when a silicon oxide precursor is supplied to a substrate including a surface of silicon oxide on which an aluminum oxide film as shown in FIG. 7 is formed and a surface of activated silicon nitride, the silicon oxide precursor is deposited on the surface of the silicon nitride to form a silicon oxide film.

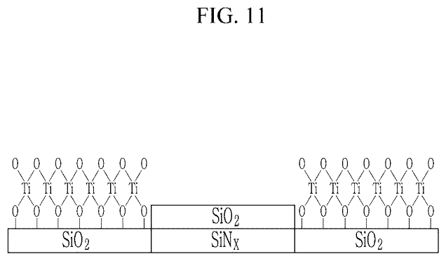

FIG. 11 is a view showing that when a silicon oxide precursor is supplied to a substrate including a surface of silicon oxide on which a titanium oxide film as shown in FIG. 8 is formed and a surface of activated silicon nitride, the silicon oxide precursor is deposited on the surface of the silicon nitride to form a silicon oxide film.

Here, the deposition of the silicon oxide precursor on the surface of the silicon nitride and its conversion into silicon oxide is the same as that described for (d) of FIG. 1, and thus a detailed description thereof is omitted.

As described in detail with reference to FIGS. 3 to 11, a method according to an embodiment selectively forms a film of a metal oxide precursor on the surface of silicon oxide through a molecular layer deposition method on a substrate including a surface of silicon oxide and a surface of silicon nitride, and then, by treating the substrate with oxygen plasma and then supplying a silicon oxide precursor, a silicon oxide film can be formed on the surface of silicon nitride. As mentioned above, silicon oxide and silicon nitride have similar chemical reactivity, and thus it is not easy to deposit silicon oxide on the surface of silicon nitride among the two surfaces including the two materials respectively. In particular, when the width of the surface of silicon nitride is very narrow, for example, less than or equal to about 5 nm, and furthermore, when a surface of silicon oxide exists on both sides of the surface of silicon nitride, forming a silicon oxide film on the surface of silicon nitride can never be achieved by a conventional lithography process that repeats exposure and etching processes through a mask. A deposition method according to an embodiment is a method of selectively synthesizing a metal oxide precursor on the surface of silicon oxide using a molecular layer deposition method, converting it into a metal oxide, and simultaneously activating the surface of silicon nitride, so that a subsequent silicon oxide precursor may be selectively deposited on the surface of the activated silicon nitride to form silicon oxide. The method according to this embodiment exhibits a surprising effect of enabling a silicon oxide film to be selectively formed even when the surface width of the silicon nitride is less than or equal to about 5 nm, that is, even when the length of the shortest line crossing the surface of silicon nitride between at least two adjacent surfaces of silicon oxide is less than about 5 nm.

Accordingly, another embodiment can provide a method of fabricating a semiconductor device including selectively forming silicon oxide on a surface of silicon nitride.

For example, the semiconductor device may be a three-dimensional semiconductor device in which silicon oxide layer and silicon nitride layer are alternately laminated, and the method of fabricating the semiconductor device may be advantageously used to form a charge trap structure of the three-dimensional semiconductor device.

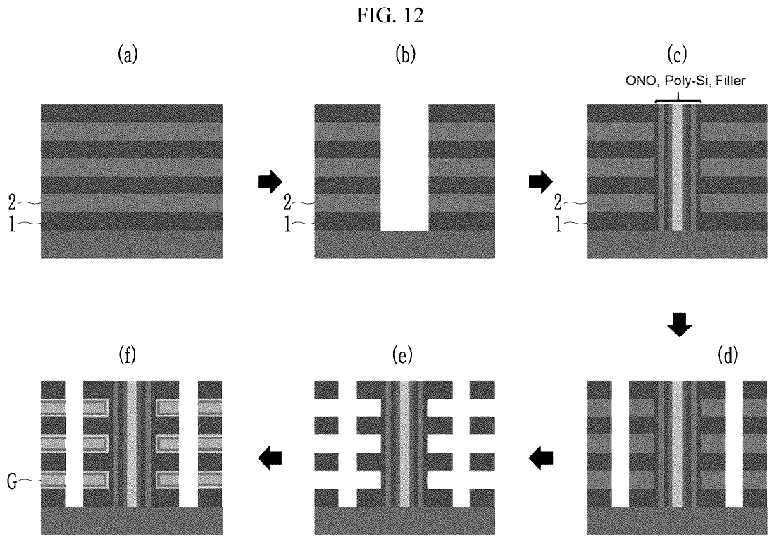

FIG. 12 is a cross-sectional view schematically illustrating a process for forming a channel opening in a three-dimensional semiconductor device using a conventional method.

Referring to FIG. 12, a gate electrode is formed by forming the channel opening (b) in a substrate on which silicon oxide 1 and silicon nitride 2 are alternately laminated (a) by using an etching method, laminating a silicon oxide layer (O) of a blocking layer, a silicon nitride layer (N) of a charge trap layer, a silicon oxide layer (O) of a tunnel oxide layer, a channel polysilicon (Poly-Si) layer, and a filler sequentially in the opening from the outside to the inside of the opening (c), cutting out a word line (WL) (d), and removing the silicon nitride 2 layer (e) by using phosphoric acid, and filling a gate (G) material where the silicon nitride layer existed (f).

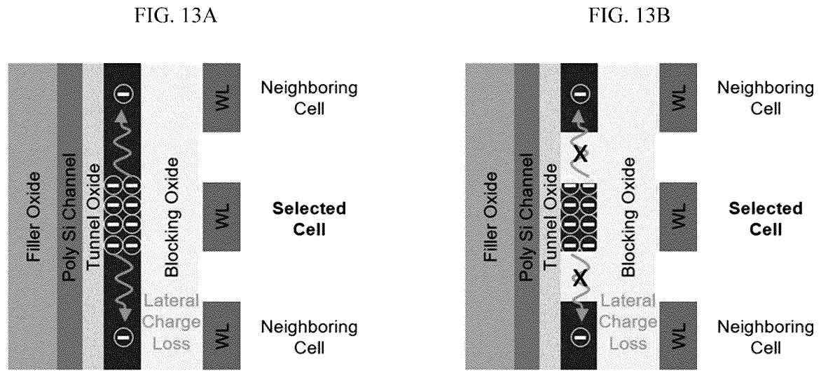

FIG. 13A is a cross-sectional view of a portion of (f) of FIG. 12, where the charge trap layer (silicon nitride layer) disposed between the tunnel oxide (silicon oxide layer) and blocking oxide (silicon oxide layer) and the gate electrode WL of the three-dimensional semiconductor device are shown.

Meanwhile, FIG. 13B is a cross-sectional view of the corresponding portion of FIG. 13A, where also the charge trap layer (silicon nitride layer) disposed between the tunnel oxide (silicon oxide layer) and blocking oxide (silicon oxide layer) and the gate electrode WL of a three-dimensional semiconductor device are shown, which is capable of being formed by the method of an embodiment.

As shown in FIG. 13A, because the charge trap layer (silicon nitride layer) formed by the method as indicated by FIG. 12 is connected even to the entire area where the gate electrode WL does not exist, electrons may freely move along the electron trap layer to where the gate electrode WL does not exist, resulting in a charge loss.

On the contrary, as shown in FIG. 13B, when the charge trap layer (silicon nitride layer) is formed in a specific region where to be overlapped with the gate electrode WL, according to an embodiment, the charges may be trapped in the specific region overlapped with the gate electrode WL, reducing the charge loss. Here, in a region that does not overlap with the gate electrode (WL), i.e., in a region where a charge trap layer (silicon nitride layer) is not formed, a metal oxide, such as, for example, aluminum oxide, zirconium oxide, titanium oxide, zinc oxide, etc., may be formed as an inhibitor so that the charge trap layer is formed only in the region that overlaps with the gate electrode (WL). In other words, the method according to an embodiment may be used to form the charge trap layer in a specific region, easily manufacturing a charge trap structure capable of reducing the charge loss, and a semiconductor device including the charge trap structure.

In an example embodiment, the method of fabricating a semiconductor device may include: providing a structure having a laminate in which a silicon oxide layer (1) and a silicon nitride layer (2) are alternately laminated, and a opening penetrating the laminate (FIG. 12(b)); selectively depositing a metal oxide precursor on an exposed surface of the silicon oxide layer (1) in the opening; providing an oxygen plasma into the opening; and supplying a silicon oxide precursor into the opening.

Referring to FIG. 12(b), an exposed side surface of silicon oxide layer (1) and an exposed side surface of silicon nitride layer (2) exist in the opening of the laminate. The method according to an embodiment can selectively deposit a precursor of a metal oxide selectively on the exposed surface of silicon oxide layer (2) among the exposed cross-sections by the same method as described with reference to FIGS. 1 to 5. Thereafter, by supplying oxygen plasma into the opening, the precursor of the metal oxide selectively deposited on the exposed cross-section of the silicon oxide layer (1) may be converted to a metal oxide, and the exposed cross-section of the silicon nitride layer (2) may be chemically activated, as described with reference to (c) of FIG. 1 and FIGS. 6 to 8. Accordingly, by supplying a precursor of silicon oxide into the opening, silicon oxide can be formed only on the surface of the silicon nitride layer (2), as described with reference to FIG. 1 and FIGS. 9 to 11. Thereafter, if necessary, the metal oxide formed on the silicon oxide layer (1) can be removed or maintained. Accordingly, unlike those shown in (c) to (f) of FIG. 12 and FIG. 13A, in FIG. 13B, silicon oxide selectively deposited only on the silicon nitride layer (2), and a charge trap layer forming material such as silicon nitride can be deposited only on the selectively deposited silicon oxide, and accordingly, as in (e) and (f) of FIG. 12, when the silicon nitride layer (2) is cut off and the gate electrode material (G) is filled, a charge trap layer may selectively formed at a position overlapping the corresponding portion, and no charge trap layer may formed in other portions, so that a semiconductor device including the same can reduce charge loss.

If the metal oxide formed on the silicon oxide layer 1 is not sufficiently removed, the semiconductor element may have metal oxide present in a region that does not overlap with the gate electrode (WL), i.e., a region where a charge trap layer (silicon nitride layer) is not formed. The metal oxide may be, for example, aluminum oxide, zirconium oxide, titanium oxide, zinc oxide, etc.

For example, the opening may be a hole or a trench.

In the method for manufacturing the semiconductor device, the precursor of the metal oxide may include a precursor of an oxide of a metal including aluminum, zinc, titanium, hafnium, zirconium, or a combination thereof, and the precursor of the metal oxide may be formed by the molecular layer deposition method described above. As the molecular layer deposition method is the same as described above, a detailed description thereof will be omitted.

In another embodiment, a semiconductor device that can be manufactured by the method is provided. The semiconductor device includes a laminate in which a first layer including a hydroxyl group, for example, a first layer including silicon oxide, and a second layer not including a hydroxyl group, for example, a second layer including silicon nitride, are alternately stacked; a silicon oxide layer selectively positioned on an exposed side surface of the second layer of the laminate; and a charge trap layer on the selectively positioned silicon oxide layer, wherein a thickness of the second layer of the laminate may be less than or equal to about 5 nm.

As described above, according to a method of selectively depositing silicon oxide, or a method of fabricating a semiconductor device using the same, a layer including a hydroxyl group, such as silicon oxide, and a layer not including a hydroxyl group, such as silicon nitride, are alternately laminated, and even when the thickness of the layer including the silicon nitride in the laminate is less than or equal to about 5 nm, silicon oxide can be selectively deposited only on the exposed side surface of the layer including the silicon nitride. Accordingly, in an embodiment, a laminate including a layer that includes silicon oxide and a layer that includes silicon nitride alternately laminated, a thickness of the layer including the silicon nitride is less than or equal to about 5 nm, and silicon oxide selectively deposited on the exposed side surface of the silicon nitride layer, and a semiconductor device including the laminate may be provided.

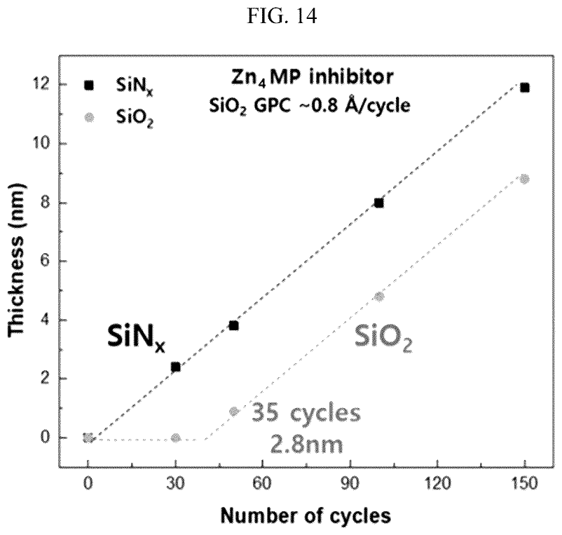

FIGS. 14 to 21 are graphs and photographs, when a silicon oxide film is formed after placing a silicon nitride substrate and a silicon oxide substrate together in a chamber capable of molecular layer deposition (MLD) and atomic layer deposition (ALD) by supplying a metal oxide precursor simultaneously to both of the substrate to apply MLD, subsequently, supplying oxygen plasma thereto, and then, supplying a silicon oxide precursor thereto according to the method of an embodiment, which show a thickness of the silicon oxide film formed on the two substrate surfaces, as the (ALD) cycle number of supplying the silicon oxide precursor is increased, that is, as time of supplying the silicon oxide precursor is increased.

FIG. 14 is a graph, when a silicon oxide film is formed by using zinc-4-mercaptophenol as a metal oxide precursor, as described in FIG. 3, and DIPAS (diisopropylaminosilane) as a silicon oxide precursor to deposit DIPAS with a thickness of about 0.8 angstrom (A) per cycle, which shows the thicknesses of the silicon oxide films on the surfaces of the silicon oxide (SiO₂) substrate and the silicon nitride (SiNx) substrate linearly increase as the numbers of cycle of supplying the silicon oxide precursor (DIPAS) increase.

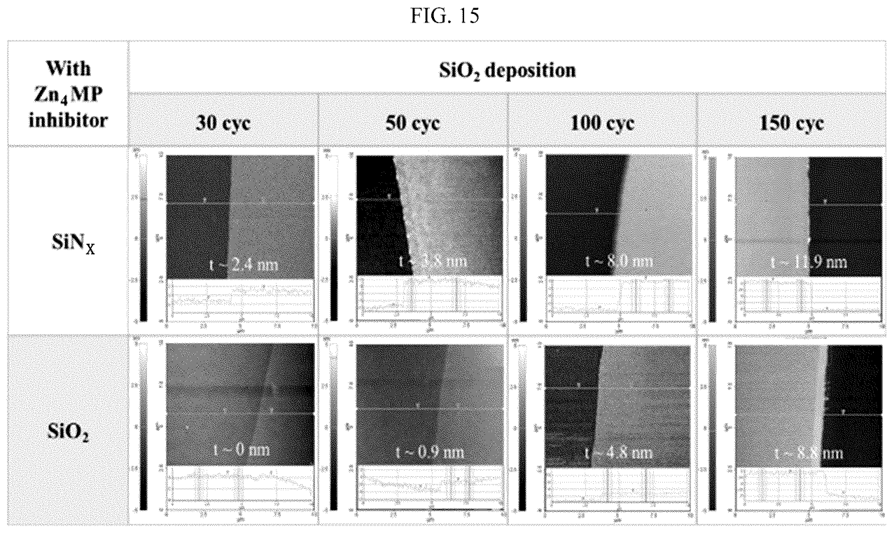

FIG. 15 is a view showing the process of measuring the thickness of a silicon oxide film deposited on the surface of each of the two substrates shown in FIG. 14. Specifically, FIG. 15 shows graphs and photographs showing a thickness of a silicon oxide film from each substrate surface of the two substrates, which is measured by atomic force microscopy (AFM), when the number of DIPAS supply cycles is 30 cycles, 50 cycles, 100 cycles, and 150 cycles. A method of measuring the thickness of the silicon oxide film with an atomic force microscope is to measure a height difference between area where the silicon oxide film is formed and area where the silicon oxide film is not formed, while scratching each surface of the substrates at each cycle number by using an AFM tip. Herein, the area where the silicon oxide film is not formed in each substrate may be formed by attaching a tape to the area where the silicon oxide film is not formed prior to the test to prevent deposition of the silicon oxide film or by growing the silicon oxide film all over the substrate without this pretreatment and then, scratching a portion of the silicon oxide film from the entire surface where the silicon oxide film is formed to remove it. With reference to this surface with no silicon oxide film, the thickness of the silicon oxide film may be measured from the surface of each substrate. In the substrate surface photographs of FIGS. 15, 17, 19, and 21, the thickness of the silicon oxide film is measured by moving the AFM tip along the line marked in each photograph.

As seen from FIG. 14, the silicon oxide (SiO₂) substrate and the silicon nitride (SiN) substrate exhibit an increase in the thickness of the silicon oxide film in proportion to an increase in the number of DIPAS supply cycles. However, while the silicon nitride (SiN) substrate exhibits an increase in the thickness of the silicon oxide film in proportion to the increase in the number of DIPAS supply cycle, as soon as DIPAS is supplied, the silicon oxide (SiO₂) substrate does not exhibit the increase in the thickness of the silicon oxide film until the number of DIPAS supply cycles reaches about 40 cycles, but starts to exhibit the increase of the thickness when the number of DIPAS supply cycles exceeds 40 cycles, and the thickness of the silicon oxide film increases in proportion to the increase in the number of cycles.

Referring to FIG. 15 together, when the number of cycles is 50, because the silicon oxide film on the silicon nitride (SiN) substrate has a thickness of about 3.8 nm, but the silicon oxide film on the silicon oxide (SiO₂) substrate has a thickness of about 0.9 nm, which show that the silicon oxide films between two substrates have a thickness difference of about 2.8 nm, indicating that the silicon oxide film may be formed to be thicker on the silicon nitride (SiN) substrate than on the silicon oxide (SiO₂) substrate. In addition, even when the number of cycles is 100, the silicon oxide film on the silicon nitride (SiN) substrate has a thickness of about 8.0 nm, while the silicon oxide film on the silicon oxide (SiO₂) substrate has a thickness of about 4.8 nm. This demonstrates that the silicon oxide films on the two substrates thickness have a thickness difference of about 3.2 nm, indicating the silicon oxide film may be formed to be thicker on the silicon nitride (SiN) substrate than on the silicon oxide (SiO₂) substrate. Even when the number of cycles is increased to 150, the silicon oxide film on the silicon nitride (SiN) substrate has a thickness of about 11.9 nm, while the silicon oxide film of the silicon oxide (SiO₂) substrate has a thickness of about 8.8 nm. This shows that the silicon oxide film of the two substrates have a thickness difference of about 3.1 nm, indicating that the silicon oxide film may be formed to be thicker on the silicon nitride (SiN) substrate than on the silicon oxide (SiO₂) substrate.

In other words, referring to the results of FIGS. 14 and 15, when the metal oxide precursor is applied according to the method of an embodiment, since the precursor is not deposited on the silicon nitride substrate, the silicon oxide film starts to grow on the silicon nitride substrate from the moment of supplying the silicon oxide precursor. However, on the silicon oxide substrate, the metal oxide precursor is converted to metal oxide after the deposition and acts as an inhibitor, preventing the formation of a silicon oxide film even if a silicon oxide precursor is supplied. Silicon oxide film may not be formed on the metal oxide inhibitor, while silicon oxide is first formed selectively on the silicon nitride substrate surface where the metal oxide inhibitor is not present. However, after more than 30 ALD cycles, the silicon oxide film starts to form even on the silicon oxide substrate where the metal oxide inhibitor is present.

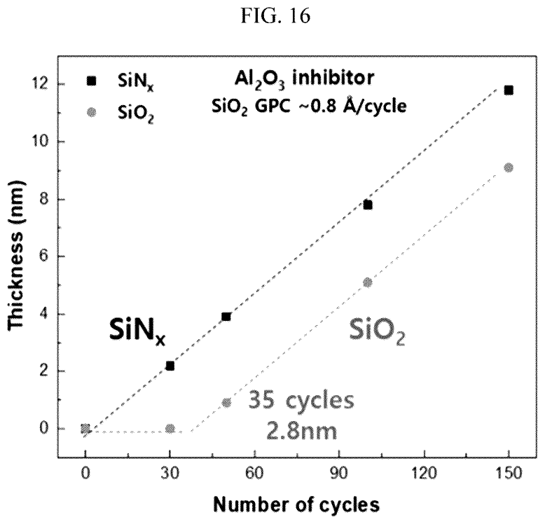

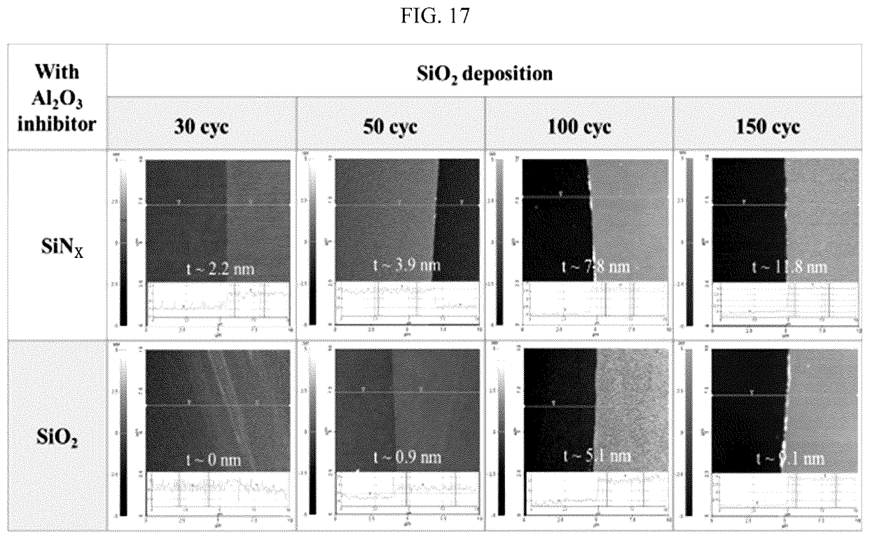

FIG. 16 is a graph showing the heights of silicon oxide deposited on the silicon oxide substrate and the silicon nitride substrate, respectively, according to the number of supply cycles of the silicon oxide precursor, by introducing a silicon oxide substrate and a silicon nitride substrate into the chamber, respectively, supplying a metal oxide precursor, and then supplying a silicon oxide precursor, using the same method as FIG. 14. FIG. 16 uses that an aluminum oxide precursor, as described in FIG. 4, instead of the zinc oxide precursor as the metal oxide precursor, which differs from the method of FIG. 14. Even though the different metal oxide precursor is used, FIG. 16 shows almost the same height of each the silicon oxide films on the silicon oxide substrate and the silicon nitride substrate and almost the same height difference of the silicon oxide films on the two substrates as those of FIG. 14. FIG. 17, in order to derive the results of FIG. 16, provides a graph and an image showing the results of measuring a height of silicon oxide deposited from each surface of the silicon oxide substrate and the silicon nitride substrate by using AFM, when the number of DIPAS supply cycles is 30 cycles, 50 cycles, 100 cycles, and 150 cycles.

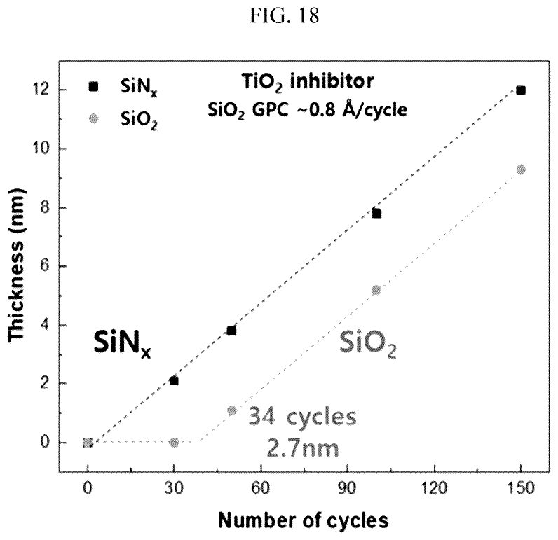

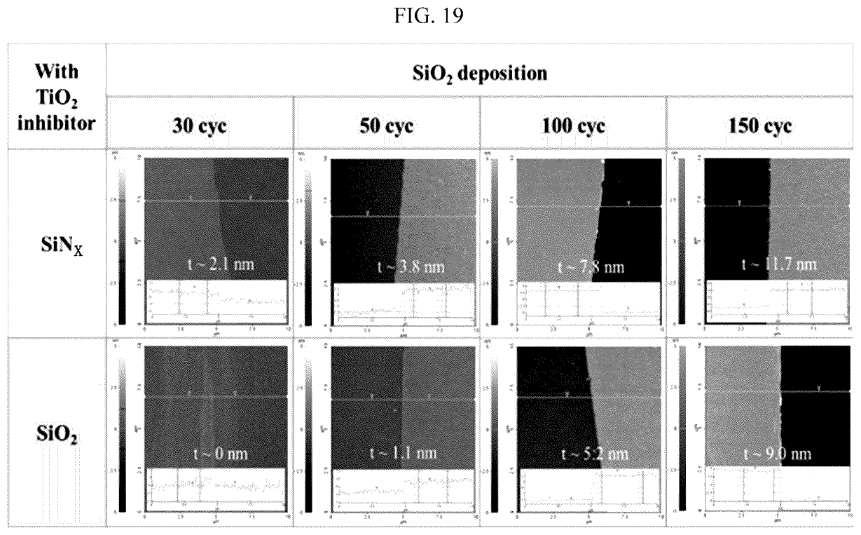

FIG. 18 is a graph showing the heights of silicon oxide deposited on the silicon oxide substrate and the silicon nitride substrate, respectively, according to the number of supply cycles of the silicon oxide precursor, by introducing a silicon oxide substrate and a silicon nitride substrate into the chamber, respectively, supplying a metal oxide precursor, and then supplying a silicon oxide precursor, using the same method as FIG. 14. FIG. 18 uses a titanium oxide precursor, as described in FIG. 5, instead of the zinc oxide precursor as the metal oxide precursor, which is different from the method of FIG. 14. Even if the different metal oxide precursor is used, FIG. 18 shows almost the same height of each silicon oxide film on the silicon oxide substrate and the silicon nitride substrate and almost the same height difference of the silicon oxide films on the two substrates and as those of FIG. 14. FIG. 19, in order to derive the results of FIG. 18, provides a graph and an image showing the results of measuring a height of silicon oxide deposited from each surface of the silicon oxide substrate and the silicon nitride substrate by using AFM, when the number of DIPAS supply cycles is 30 cycles, 50 cycles, 100 cycles, and 150 cycles.

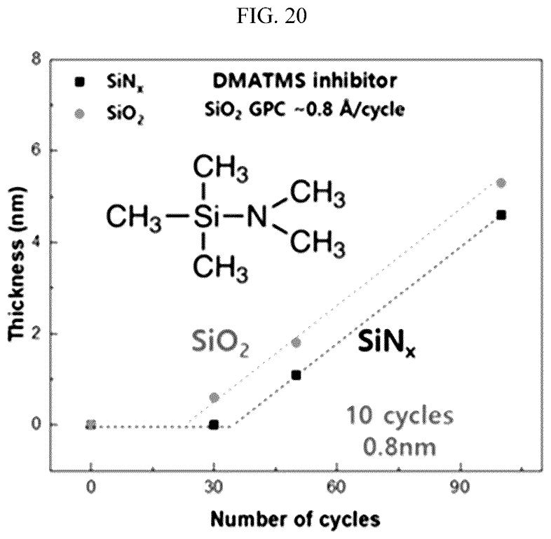

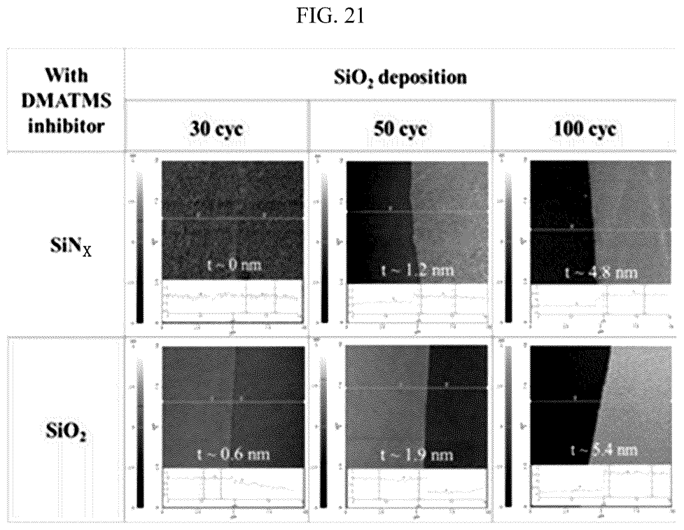

FIG. 20, unlike an embodiment, provides a graph, when a silicon oxide film is formed by first depositing dimethylaminotrimethyl silane (DMATMS), an organosilane compound, instead of the metal oxide precursor, performing an oxygen plasma treatment, and subsequently, depositing a silicon oxide precursor (DIPAS) through ALD, which shows thicknesses of the silicon oxide films from each surface of the silicon oxide substrate and the silicon nitride substrate as the number of DIPAS supply cycles is increased. In addition, FIG. 21, in order to derive the results of FIG. 20, provides a graph and an image showing the results of measuring a height of silicon oxide deposited from each surface of the silicon oxide substrate and the silicon nitride substrate by using AFM, when the number of DIPAS supply cycles is 30 cycles, 50 cycles, and 100 cycles.

Referring to FIGS. 20 and 21, opposite to the results of FIGS. 14 to 19, the silicon oxide film grows faster on the silicon oxide (SiO₂) substrate than on the silicon nitride (SiNx) substrate. This is because the dimethylaminotrimethyl silane (DMATMS) does not stably exist unlike the metal oxide precursor according to an embodiment but is converted to a silicon oxide precursor by the oxygen plasma treatment, allowing the silicon oxide precursor to potentially exist on the surface of the silicon oxide substrate before being supplied to the substrate. If the silicon oxide precursor is supplied, the silicon oxide film may grow more rapidly on the silicon oxide substrate surface. Additionally, as the number of cycles increases, the silicon oxide film deposited on the silicon oxide substrate may become thicker than that deposited on the silicon nitride substrate. In other words, since the silicon oxide film starts to grow on the silicon oxide substrate before the DIPAS supply cycles reach 30, and the silicon oxide film quickly starts to grow on the surface of the silicon nitride substrate after the oxygen plasma treatment, the silicon oxide films on the two substrates may differ in thickness difference by about 0.8 nm, which is reduced to about ⅓ of the results of FIGS. 14 to 19.

In other words, according to an embodiment, on a substrate including two surfaces with similar chemical reactivity such as silicon oxide and silicon nitride, a metal oxide precursor is selectively deposited on the surface of silicon oxide alone, while a silicon oxide film is selectively formed on the surface of silicon nitride where the metal oxide precursor is not present. However, using a conventional organosilane compound as a precursor instead of the metal oxide precursor in an embodiment may make it difficult to achieve this selective deposition of the silicon oxide on the surface of silicon nitride.

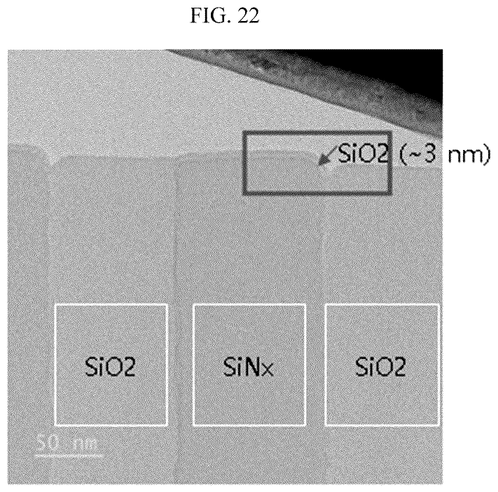

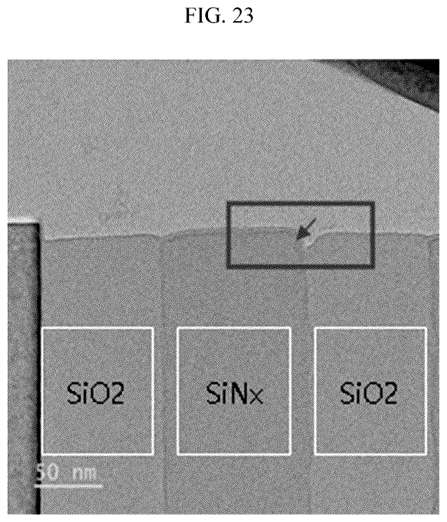

FIG. 22 is a transmission electron microscopy (TEM) photograph showing the result of forming a silicon oxide (SiO₂) film by depositing zinc-4-mercaptophenol precursor as a metal oxide precursor on a substrate alternately stacking silicon oxide (SiO₂) and silicon nitride (SiNx), and then supplying a silicon oxide precursor (DIPAS), according to an embodiment, and FIG. 23 is a TEM photograph similar to FIG. 22 showing the result of forming a silicon oxide (SiO₂) film by using aluminum-phenol as a metal oxide precursor.

Referring to FIGS. 22 and 23, the method of an embodiment is confirmed to form the silicon oxide film with a thickness of about 3 nm on the surface of silicon nitride.

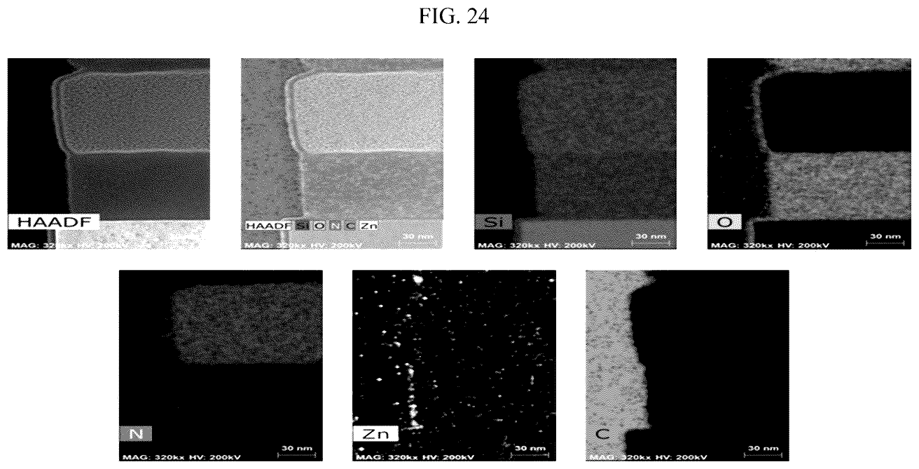

FIG. 24 is an image showing the analysis results by energy dispersive spectroscopy (EDS) for the substrate shown in FIG. 22. Referring to FIG. 24, silicon (Si), oxygen (O), and nitrogen (N) are confirmed to be distributed in the substrate in which silicon oxide (SiO₂) and silicon nitride (SiNx) are alternately laminated, as shown in FIG. 22, which confirms that the substrate is in the form of alternating layers of silicon oxide (SiO₂) and silicon nitride (SiNx). Furthermore, the presence of a thin film of oxygen (O) on part, where silicon nitride (SiNx) is present but oxygen does not exist underneath it, indicates that a silicon oxide (SiO₂) film is formed on the silicon nitride (SiNx) surface of the substrate. In addition, zinc (Zn) derived from the metal oxide precursor (zinc-4-mercaptophenol) may be confirmed to exist as a thin film on the silicon oxide (SiO₂), indicating that zinc oxide is formed on the silicon oxide (SiO₂) surface and acts as an inhibitor, allowing the silicon oxide precursor to be substantially, selectively deposited on the silicon nitride (SiNx) surface.

On the other hand, in the present specification, the substrate including the surface of silicon oxide and the surface of silicon nitride is mainly illustrated as a substrate for applying the method according to an embodiment, but it will be apparent to those skilled in the art that the method of an embodiment is not limited to the substrate. The embodiment may be equally applied to a substrate having a first surface including hydroxyl group (—OH) and a second surface adjacent to the first surface and not including hydroxyl group, such that a metal oxide precursor may be selectively deposited on the first surface.

Although the embodiments of the present invention have been described above, it is clear that the present invention is not limited to these embodiments, and that all changes or modifications obvious to a person skilled in the art from the appended claims and the like fall within the scope of the present invention.

What is claimed is:

1. A method of selectively depositing silicon oxide on a substrate, the method comprising:
providing a substrate that includes a first surface comprising silicon oxide and a second surface comprising silicon nitride in a deposition chamber;
selectively depositing a metal oxide precursor on the first surface of the substrate;
treating the substrate with an oxygen plasma; and
supplying the substrate with a silicon oxide precursor.

2. The method of claim 1, wherein the treating the substrate with the oxygen plasma comprises converting the metal oxide precursor deposited on the first surface into a metal oxide.

3. The method of claim 1, wherein the metal oxide precursor is an oxide precursor of a metal comprising aluminum, zinc, titanium, hafnium, zirconium, or a combination thereof.

4. The method of claim 1, wherein the selectively depositing the metal oxide precursor comprises depositing a first reactant comprising a metal on the first surface, and supplying a second reactant comprising a phenyl group or a biphenyl group.

5. The method of claim 4, wherein the first reactant comprises an organic compound of the metal, a halide of the metal, an alkoxide of the metal, an amine compound of the metal, or a combination thereof.

6. The method of claim 4, wherein the first reactant comprises trimethyl aluminum, trichloro aluminum, diethyl amine, (ethylcyclopentadienyl)tris(dimethylamido)titanium(IV), titanium tetramethoxide, tetrakis(diethylamido)titanium(IV), tetrakis(dimethylamido)titanium(IV), titanium tetrachloride, titanium(IV) isopropoxide, tetrakis(diethylamino)hafnium(IV), hafnium(IV) chloride, hafnium(IV) t-butoxide, tetrakis(dimethylamino)hafnium(IV), zirconium-t-(butoxide)₄, tetrakis(dimethylamino)zirconium, zirconium(IV) chloride, or a combination thereof.

7. The method of claim 4, wherein the second reactant comprises a substituted or unsubstituted phenol or a substituted or unsubstituted biphenyl group-containing compound.

8. The method of claim 7, wherein the substituted or unsubstituted phenol comprises an unsubstituted phenol, a mercapto phenol, a phenol substituted with an alkyl group, a phenol substituted with a fluorine and an alkyl group, or a combination thereof.

9. The method of claim 1, wherein the silicon oxide precursor is deposited on the second surface treated with the oxygen plasma by atomic layer deposition to form silicon oxide.

10. The method of claim 1, wherein the silicon oxide precursor comprises an amino silane compound, an alkoxy silane compound, a silane halide, or a combination thereof.

11. The method of claim 1, wherein the silicon oxide precursor comprises silicon tetrachloride, tetraethyl orthosilicate, diisopropylaminosilane, bis(diethylamino)silane, or a combination thereof.

12. The method of claim 1, wherein the metal oxide precursor is represented by Chemical Formula 1: 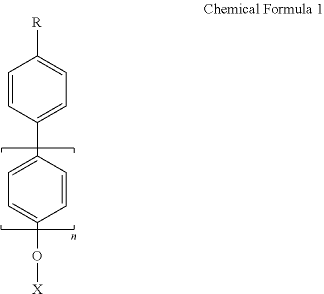
wherein, in Chemical Formula 1, R is hydrogen, a C1 to C10 alkyl group, a halogen atom, or a mercapto group,
X is Al, Zn, Ti, Hf, or Zr, coordinated without or with an organic group, and
n is 0 or 1.

13. The method of claim 2, wherein the method further comprises removing the metal oxide on the first surface after treating the substrate with the silicon oxide precursor.

14. The method of claim 1, wherein a width of the second surface is less than or equal to about 5 nanometers.

15. A method of fabricating a semiconductor device comprising:
providing a structure having a laminate in which a silicon oxide layer and a silicon nitride layer are alternately laminated, and an opening penetrating the laminate,
selectively depositing a metal oxide precursor on an exposed surface of the silicon oxide layer in the opening;
supplying an oxygen plasma into the opening; and
supplying a silicon oxide precursor into the opening.

16. The method of claim 15, wherein the metal oxide precursor is an oxide precursor of a metal comprising aluminum, zinc, titanium, hafnium, zirconium, or a combination thereof.

17. The method of claim 15, wherein the supplying oxygen plasma into the opening comprises converting the metal oxide precursor deposited on the exposed surface of the silicon oxide layer in the opening into a metal oxide.

18. The method of claim 17, wherein the method further comprises removing the metal oxide after the supplying the silicon oxide precursor into the opening.

19. The method of claim 15, wherein in the opening of the structure a first exposed surface including silicon oxide and a second exposed surface including silicon nitride exist, and wherein a width of the second exposed surface is less than or equal to about 5 nanometers.

20. The method of claim 15, wherein the selectively depositing the metal oxide precursor comprises:
depositing a first reactant including a metal on the exposed surface of the silicon oxide layer, and
supplying a second reactant including a phenyl group or a biphenyl group.
